(19) United States
(12) Patent Application Publication
(10) Pub. No.: US 2011/0132756 A1
(43) Pub. Date: Jun. 9, 2011

(54) SPUTTERING DEVICE

(75) Inventor: CHUNG-PEI WANG, Tu-Cheng (TW)

(73) Assignee: HON HAI PRECISION INDUSTRY CO., LTD., Tu-Cheng (TW)

(21) Appl. No.: 12/824,437

(22) Filed: Jun. 28, 2010

(30) Foreign Application Priority Data
Dec. 3, 2009 (CN) 200910310786.6

(51) Int. Cl. C23C 14/34

(52) U.S. Cl. 204/298.12

(57) ABSTRACT

A sputtering device includes a housing and a transporting mechanism. The housing defines a sputtering chamber. The transporting mechanism includes a first drive gear, a second drive gear adjacent to the first drive gear, a driving track, a transporting belt, a plurality of slave gears and a plurality of hanging poles. The driving track includes a first track surrounding the first drive gear, a second track surrounding the second drive gear, and a first connection track connecting the first track to the second track. The transporting belt is movably arranged on the driving track. The slave gears are pivotably connected to the transporting belt. The hanging poles are mounted on the salve gears and are configured for hanging the workpieces.

### BACKGROUND

1. Technical Field

The present disclosure relates to sputtering devices, particularly, to a sputtering device capable of preventing targets from contaminating each other during sputtering.

2. Description of Related Art

Sputtering is commonly used for thin film deposition. In certain conditions workpieces may need multiple thin film layers. Different targets are thus needed and are usually bombarded in the same chamber of a sputtering device. However, the different targets bombarded in the same chamber may tend to contaminate each other.

Therefore, what is needed is a sputtering device to overcome the described shortcoming.

### BRIEF DESCRIPTION OF THE DRAWINGS

FIG. 1 is a schematic, cross-sectional view of a sputtering device in accordance with an exemplary embodiment.

FIG. 2 is similar to FIG. 1, but showing some workpieces moved to a first connection track.

FIG. 3 is similar to FIG. 2, but showing some workpieces moved to a second track.

FIG. 4 is similar to FIG. 1, but showing a cross-sectional view of a sputtering device in accordance with another embodiment.

### DETAILED DESCRIPTION

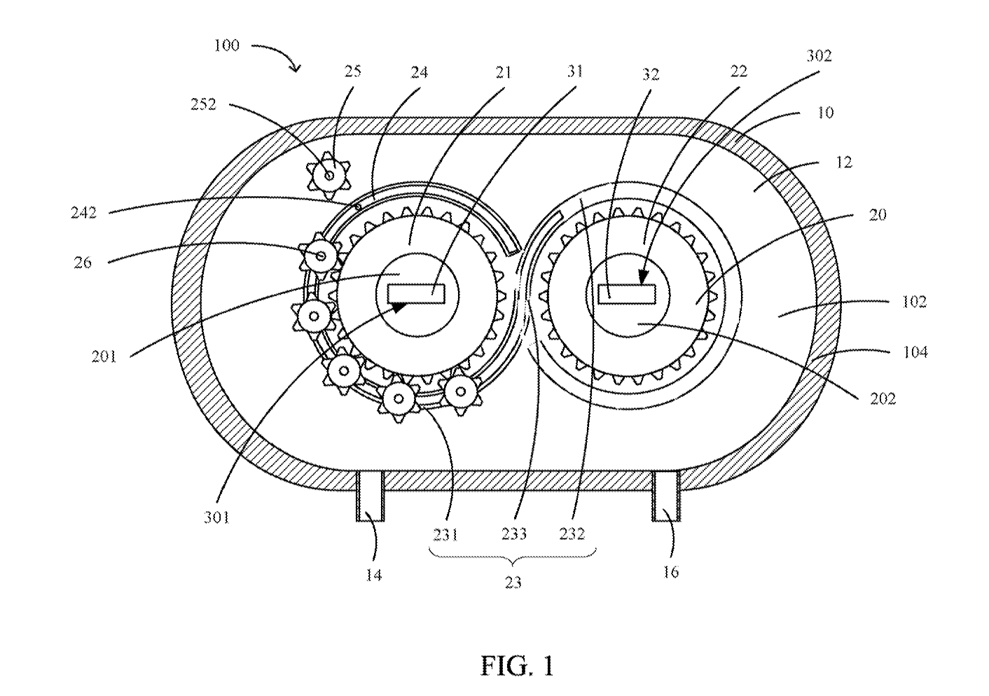

Referring to FIG. 1, a sputtering device 100 in a first embodiment is provided. The sputtering device 100 includes a housing 10 and a transporting mechanism 20.

The housing 10 includes a top wall (not shown), a bottom wall 102, and a sidewall 104 connected to the top wall and the bottom wall 102. The top wall cooperates with the bottom wall 102 and the sidewall 104 to form a sputtering chamber 12. In the embodiment, the sidewall 104 defines an intake 14 and an outlet 16 communicating with the sputtering chamber 12. Reactant gas enters the sputtering chamber 12 through the intake 14 and is vented through the outlet 16.

The transporting mechanism 20 is arranged within the sputtering chamber 12. The transporting mechanism 20 includes a first drive gear 21, a second drive gear 22, a driving track 23, a transporting belt 24, a plurality of slave gears 25, and a plurality of hanging poles 26.

The first drive gear 21 and the second drive gear 22 can be driven by a motor (not shown) to rotate clockwise or counterclockwise. The motor may be fixed to the bottom wall 102 of the housing 10.

The driving track 23 includes a first track 231 surrounding the first drive gear 21, a second track 232 surrounding the second drive gear 22, and a first connection track 233 connecting the first track 231 to the second track 232. The first connection track 233 is located between the first drive gear 21 and the second drive gear 22. In the embodiment, the first track 231 and the second track 232 are substantially arc shaped. In the embodiment, the arc angle of the first track 231 and the second track 232 exceed 90 degrees. The center of the first track 231 coincides with the center of the first drive gear 21. The arc center of the second track 232 coincides with the center of the second drive gear 22. The curvature radius of the first track 231 equals that of the second track 232.

The transporting belt 24 is movably arranged on the driving track 23. In the embodiment, the transporting belt 24 can be driven to move with respect to the driving track 23 by a plurality of driving wheels (not shown) under the driving track 23. In another embodiment, the transporting belt 24 may includes a plurality of teeth defined in a sidewall thereof that engage a plurality of gears (not shown) arranged in the driving track 23. The transporting belt 24 can thus be driven to move by the plurality of gears. In the embodiment, the width of the transporting belt 24 is less than that of the driving track 23, thereby preventing the transporting belt 24 deviating from the driving track 23. The transporting belt 24 defines a plurality of fixing holes 242 formed in a middle portion of the transporting belt 24. The distance between every two adjacent fixing holes 242 is substantially the same. The length of the transporting belt 24 exceeds the length of the outer perimeter of the first track 231 or the second track 232 whichever has a greater curvature radius, and is less than 1.5 times the length of the outer perimeter of the first track 231 or the second track 232 whichever has a smaller curvature radius. In the embodiment, because the curvature radius of the first track 231 equals that of the second track 232, the length of the transporting belt 24 exceeds the length of the outer perimeter of the first track 231 and is less than 1.5 times.

The plurality of slave gears 25 are pivotably connected to the transporting belt 24. In the embodiment, each slave gear 25 includes a shaft rotatably received in one of the plurality of fixing holes 242, thereby rotatably connecting the slave gears 25 to the transporting belt 24. When the transporting belt 24 moves along the driving track 23, the slave gears 25 move together with the transporting belt 24. The plurality of slave gears 25 can also be rotated by engagement of the first drive gear 21 with the second drive gear 22. In the embodiment, each slave gear 25 defines a holding hole 252 arranged in the center thereof.

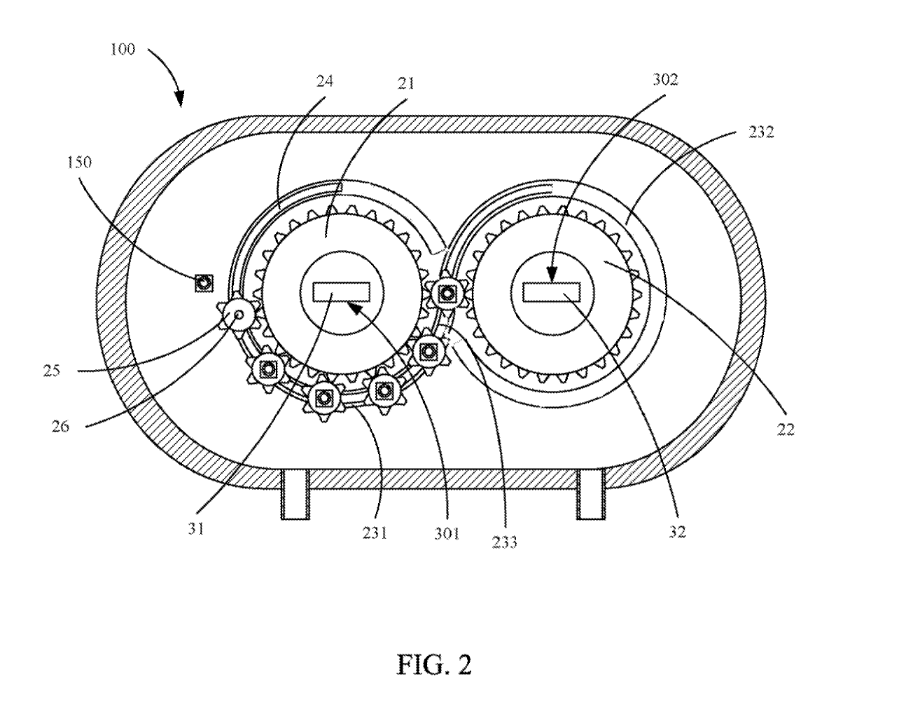

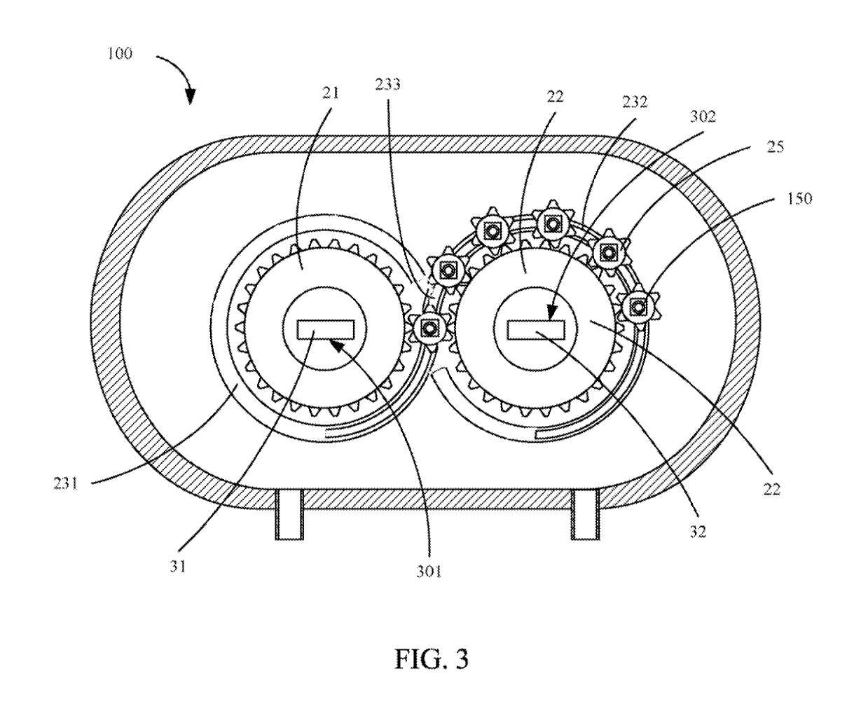

Referring to FIGS. 2-3, the hanging poles 26 are configured for hanging a plurality of workpieces 150. One end of each hanging pole 26 is securely received in the corresponding holding hole 252 of the slave gears 25. The hanging poles 26 can thus move together with the slave gears 25. The workpieces 150 can thus be transported along the first track 231 to the first connection track 233, and then to the second track 232. Because the slave gears 25 can rotate about the central axis of the corresponding fixing hole 242, the hanging poles 26 can also rotate about the central axis of the corresponding holding hole 252.

A first target 31 is arranged in the center of the first track 231. The first target 31 includes a first target surface 301. When the first target 31 is bombarded by energetic particles, the particles are ejected from the first target surface 301.

A second target 32 is arranged in the center of the second track 232. The second target 32 includes a second target surface 302. When the second target 32 is bombarded by energetic particles, the particles are ejected from the second target surface 302. In the embodiment, the orientation of the second target surface 302 is opposite to that of the first target surface 301. Atoms from the first target surface 301 will never be ejected onto the second target 32, and particles from the second target surface 302 will never be ejected onto the first target 31. Mutual contamination between the first target 31 and the second target 32 can thus be avoided.

Because the first target 31 is set in the arc center of the first track 231, the second target 32 is set in the arc center of the second track 232, the distances between every workpiece 150 and the first target 31 are equal in the first track 231, and the distances between every workpiece 150 and the second target 32 are equal in the second track 232, the thickness of the first layer sputtered onto surfaces of the workpieces 150 is equal that of the second layer sputtered onto the surfaces of the workpieces 150.

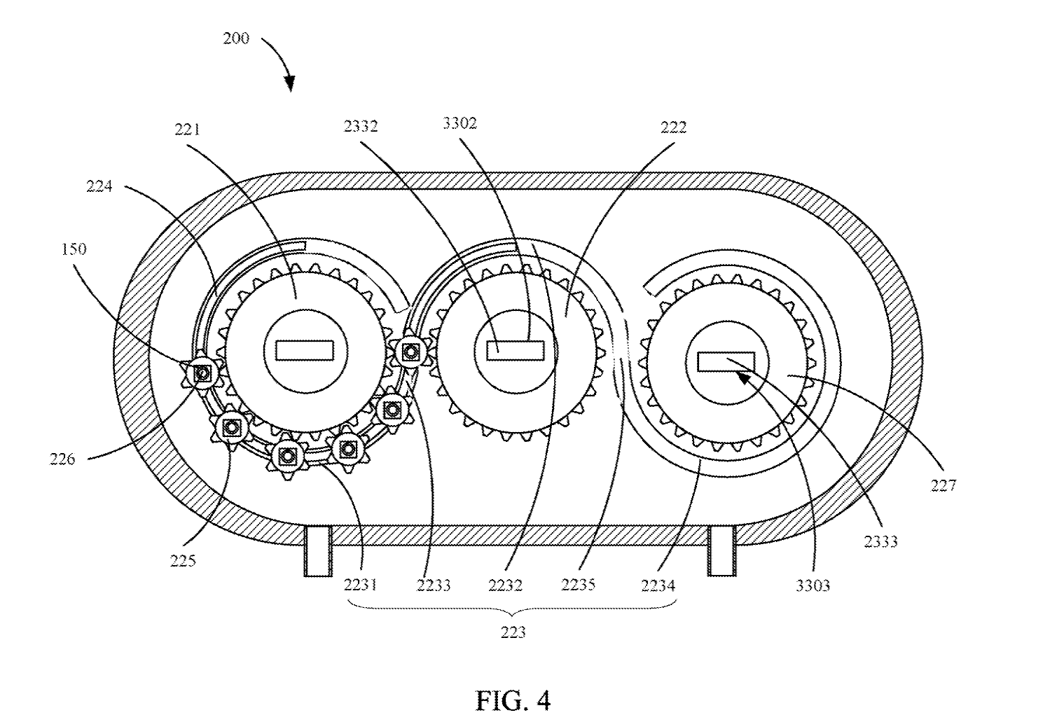

Referring to FIG. 4, a sputtering device 200 according to a second embodiment is provided. The sputtering device 200 has a structure substantially the same as the sputtering device 100. The difference between the sputtering devices 100 and 200 is that the sputtering device 200 further includes a third drive gear 227 and a driving track 223. The driving track 223 includes a third track 2234, a second connection track 2235 connecting the second track 2232 to the third track 2234, and a third target 2333. The second connection track 2235 is located between the second drive gear 222 and the third drive gear 227.

In the embodiment, the third drive gear 227 is adjacent to the second drive gear 222. The first drive gear 221, the second drive gear 222, and the third drive gear 227 are arranged linearly.

When the transporting belt 224 moves along the driving track 223, the slave gears 225 move together with the transporting belt 224. The slave gears 225 can also be rotated by engagement of the first drive gear 221, the second drive gear 222, and the third drive gear 227. The workpieces 150 can thus be transported along the first track 2231 to the first connection track 2233, along the first connection track 2233 to the second track 2232, along the second track 2232 to the second connection track 2235, and then to the third track 2234. In the embodiment, the curvature radiuses of the first track 2231, the second track 2232 and the third track 2234 are equal.

A third target 2333 is arranged in the center of the third track 2234. The third target 2333 includes a third target surface 3303. When the third target 2333 is bombarded by energetic particles, the particles are ejected from the third target surface 3303. In the embodiment, the orientation of the third target surface 3303 is opposite to that of the second target surface 3302. Particles from the second target surface 3302 will never be ejected onto the third target 2333, while atoms from the third target surface 3303 will never be ejected onto the second target 2332. Mutual contamination between the second target 2332 and the third target 2333 can thus be avoided.

The length of the transporting belt 224 exceeds the length of the outer perimeter of the first track 2231, or the second track 2232, or the third track 2234 whichever has a greatest curvature radius, and is less than 1.5 times the length of the outer perimeter of the first track 2231, or the second track 2232, or the third track 2234 whichever has a smallest curvature radius. In the embodiment, because the curvature radiuses of the first track 2231, the second track 2232 and the third track 2234 are equal, the length of the transporting belt 224 exceeds the length of the outer perimeter of the first track 2231, and is less than 1.5 times the length of the outer perimeter of the first track 2231, thereby driving the slave gears 225 to drive the workpieces 150 hung on the hanging poles 226 to receive a first sputtered layer in the first track 2231, a second sputtered layer in the second track 2232, and a third sputtered layer in the third track 2234.

The number of the drive gears, the targets, and the driving track of the sputtering device may be changed according to need.

Although the present disclosure has been specifically described on the basis of the embodiments thereof, the disclosure is not to be construed as being limited thereto. Various changes or modifications may be made to the embodiments without departing from the scope and spirit of the disclosure.

What is claimed is:

1. A sputtering device, comprising:
a housing defining a sputtering chamber; and
a transporting mechanism arranged within the sputtering chamber, and configured for transporting workpieces, the transporting mechanism comprising:
a first drive gear;
a second drive gear adjacent to the first drive gear;
a driving track comprising a first track surrounding the first drive gear, a second track surrounding the second drive gear, and a first connection track connecting the first track to the second track, wherein the first track and the second track are substantially arc shaped, the first connection track is located between the first drive gear and the second drive gear;
a transporting belt movably arranged on the driving track;
a plurality of slave gears pivotably connected to the transporting belt, wherein when the transporting belt moves along the driving track, the slave gears move together with the transporting belt, and the salve gears are caused to rotate by engagement of the first drive gear or the second drive gear; and
a plurality of hanging poles configured for hanging the workpieces, and mounted on the slave gears;
wherein, a first target is arranged in a center of the first track, and comprises a first target surface, a second target is arranged in a center of the second track, and comprises a second target surface, the orientation of the first target surface is opposite to that of the second target surface, thereby preventing the first target and the second target from contaminating each other.

2. The sputtering device as described in claim 1, wherein the arc angle of the first track or the second track exceed 90 degrees.

3. The sputtering device as described in claim 1, wherein the arc center of the first track coincides with the center of the first drive gear, and the arc center of the second track coincides with the center of the second drive gear.

4. The sputtering device as described in claim 1, wherein the length of the transporting belt exceeds the length of the outer perimeter of the first track or the second track whichever has a greater curvature radius, and is less than 1.5 times the length of the outer perimeter of the first track or the second track whichever has a smaller curvature radius.

5. The sputtering device as described in claim 1, wherein the curvature radius of the first track equals that of the second track.

6. The sputtering device as described in claim 1, wherein the transporting belt defines a plurality of fixing holes formed in a middle portion of the transporting belt, each of the slave gears comprises a shaft rotatably received in one of the plurality of fixing holes, thereby rotatably connecting the slave gears to the transporting belt.

7. The sputtering device as described in claim 1, wherein each of the slave gear defines a holding hole arranged in the center thereof, one end of each of the hanging poles is securely received in the holding holes of the salve gears.

8. The sputtering device as described in claim 1, further comprising a third drive gear and a third target, wherein the driving track comprises a third track surrounding the third drive gear, and a second connection track connecting the second track to the third track, the third track is adjacent to the second track, the second connection track is located between the second drive gear and the third drive gear, and the third target is arranged in the center of the third track.

9. The sputtering device as described in claim 8, wherein the central axis of the first drive gear, the second drive gear and the third drive gear are arranged linearly.

10. The sputtering device as described in claim 1, wherein the width of the transporting belt is less than that of the driving track, thereby preventing the transporting belt deviating from the driving track.

11. The sputtering device as described in claim 1, wherein the housing defines an intake and an outlet communicating with the sputtering chamber, reactant gas enters the sputtering chamber through the intake and is vented through the outlet.
